(19) United States
(12) Patent Application Publication
(10) Pub. No.: US 2017/0365718 A1
(43) Pub. Date: Dec. 21, 2017

(54) INSULATOR/METAL PASSIVATION OF MOTFT

(71) Applicants: Chan-Long Shieh, Paradise Valley, AZ (US); Gang Yu, Santa Barbara, CA (US); Guangming Wang, Santa Barbara, CA (US)

(72) Inventors: Chan-Long Shieh, Paradise Valley, AZ (US); Gang Yu, Santa Barbara, CA (US); Guangming Wang, Santa Barbara, CA (US)

(21) Appl. No.: 15/188,762

(22) Filed: Jun. 21, 2016

(51) Int. Cl. H01L 29/786; H01L 21/477; H01L 29/66; H01L 21/467

(52) U.S. Cl. CPC H01L 29/7869; H01L 29/78606; H01L 21/467; H01L 21/477; H01L 29/66969

(57) ABSTRACT

A method of passivating a MOTFT including providing a metal oxide thin film transistor having a surface defined by spaced apart source/drain terminals positioned on a layer of semiconductor metal oxide and material in a space between the source/drain terminals, the space between the source/drain terminals defining a conduction channel in the layer of semiconductor metal oxide. Forming a layer of passivation material on the surface defined by the spaced apart source/drain terminals and the material in the space between the source/drain terminals. Establishing oxygen vacancy equilibrium in the conduction channel of the layer of semiconductor metal oxide by annealing in an oxygen containing ambient the MOTFT and layer of passivation material and depositing a layer including a noble metal, a refractory metal, and/or a transparent conducting metal oxide on the layer of passivation material overlying the space between the source/drain terminals.

### FIELD OF THE INVENTION

This invention generally relates to passivation of metal oxide thin film transistors to improve environmental stability.

### BACKGROUND OF THE INVENTION

Metal Oxide Thin Film Transistors (MOTFT) get a lot of interest because of their high performance, including high mobility, better positive/negative bias stress stability, and better current stress stability. But challenges remain in the area of environmental stability.

Many processing steps have to be performed after the fabrication of MOTFTs to incorporate the MOTFTs into displays or sensors. These processing steps may require moderate temperatures (>200° C.) under all kinds of ambience (vacuum, inert, reducing or oxidizing, etc.). Furthermore, all electronic devices are sensitive to humidity, which they have to be protected against.

The best passivation film that protects against humidity is silicon nitride (SiN). The silicon nitride is typically deposited by low pressure chemical vapor deposition (LPCVD) at high temperature (>400° C.). Silicon nitride can also be deposited by plasma enhanced chemical vapor deposition (PECVD) at lower temperature (>200° C.). In the flat panel display industry, LPCVD is not available because of the high deposition temperature and PECVD is the only option.

The quality of PECVD SiN depends critically on the deposition temperature. The higher the deposition temperature is the better the quality of the SiN, i.e. as the deposition temperature is increased the film density, and thus the passivation quality, increases. However, a high mobility MOTFT can only survive a high temperature of approximately 200° C. in an oxidizing ambience because the MOTFT needs balancing internal oxygen vacancies with the ambience oxygen so that no further vacancies can be generated. The generation of additional oxygen vacancies (loss of oxygen) in the MOTFT will change the threshold voltage by moving the threshold voltage more negative. If the ambience is reducing (i.e. oxygen absorbing), the loss of oxygen from the metal oxide semiconductor material in the MOTFT will not stop. If the processing temperature is high, the diffusion through whatever material is on top of the metal oxide semiconductor material can be fast and the loss of oxygen fast enough to change the threshold voltage toward negative substantially. So MOTFT passivation becomes the major hurdle in the adoption by the flat panel display industry. The major passivation technique in the flat panel display industry today is the use of PECVD SiN. No flat panel display can be made without PECVD SiN passivation. To make MOTFT widely adopted by the TFT/flat panel industry, any passivation needs to be compatible with the standard passivation technology, namely PECVD SiN.

SiN passivation was originally adapted from the silicon industry into the amorphous silicon (a-Si) TFT industry. Because a-Si can withstand relatively high temperature, PECVD is very compatible with the a-Si TFT technology. But in the PECVD process of SiN, there are lots of hydrogen ions and molecules in the plasma. The ambience is not oxidizing, but can be reducing (removing or absorbing oxygen). The hydrogen ions or molecules can diffuse through whatever is on top of the metal oxide semiconductor material (e.g. partially completed SiN layer) at high temperature and reduce the metal oxide semiconductor material into metal ions. This reduction can move the threshold voltage negatively by a large amount.

It would be highly advantageous, therefore, to remedy the foregoing and other deficiencies inherent in the prior art.

Accordingly, it is an object of the present invention to provide new and improved passivation of MOTFTs.

It is another object of the present invention to provide a new and improved process and material for passivation of MOTFTs that improves environmental stability.

It is another object of the present invention to provide a new and improved process and material for passivation of MOTFTs that is compatible with flat panel technology.

### SUMMARY OF THE INVENTION

The desired objects of the instant invention are achieved in accordance with a method of fabricating a MOTFT including providing a metal oxide thin film transistor having a surface defined by spaced apart source/drain terminals positioned on a layer of semiconductor metal oxide and material in a space between the source/drain terminals, the space between the source/drain terminals defining a conduction channel in the layer of semiconductor metal oxide. The method further includes the steps of forming a layer of passivation material on the surface defined by the spaced apart source/drain terminals and the material in the space between the source/drain terminals, establishing oxygen vacancy equilibrium in the conduction channel of the layer of semiconductor metal oxide by annealing in an oxygen containing ambient the MOTFT and layer of passivation material and depositing at low temperature a layer including a noble metal, a refractory metal, and/or a transparent conducting metal oxide on the layer of passivation material overlying the space between the source/drain terminals.

The desired objects of the instant invention are also achieved in accordance with a specific embodiment thereof wherein a passivated metal oxide thin film transistor (MOTFT) is provided. The MOTFT includes a metal oxide thin film transistor having a surface defined by spaced apart source/drain terminals positioned on a layer of semiconductor metal oxide and material in a space between the source/drain terminals, the space between the source/drain terminals defining a conduction channel in the layer of semiconductor metal oxide. A layer of passivation material is positioned on the surface defined by the spaced apart source/drain terminals and the material in the space between the source/drain terminals and a layer including a noble metal, a refractory metal, and/or a transparent conducting metal oxide is positioned on the layer of passivation material overlying the space between the source/drain terminals.

The desired objects of the instant invention are also achieved in accordance with a method of fabricating a back-panel with a plurality of metal oxide thin film transistors for flat panel devices including one of a light emitting diode display, an image sensor array, a biosensor array, a pressure sensing array, an X-ray imager, or a touch sensing array. The method includes steps of providing a substrate, and fabricating on the substrate a plurality of passivated metal oxide thin film transistors, the fabrication of each passivated transistor including the steps of:

providing a metal oxide thin film transistor having a surface defined by spaced apart source/drain terminals positioned on a layer of semiconductor metal oxide and material in a space between the source/drain terminals, the space between the source/drain terminals defining a conduction channel in the layer of semiconductor metal oxide;

forming a layer of passivation material on the surface defined by the spaced apart source/drain terminals and the material in the space between the source/drain terminals;

establishing oxygen vacancy equilibrium in the conduction channel of the layer of semiconductor metal oxide by annealing in an oxygen containing ambient the metal oxide thin film transistor and layer of passivation material; and

depositing a layer including a noble metal, a refractory metal, and/or a transparent conducting metal oxide on the layer of passivation material overlying the space between the source/drain terminals.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram illustrating an etch-stop type of MOTFT with improved environmental stability passivation in accordance with the present invention; and

FIG. 2 is a simplified layer diagram illustrating a back channel etch (BCE) type of MOTFT with improved environmental stability passivation in accordance with the present invention.

### DETAILED DESCRIPTION OF THE DRAWINGS

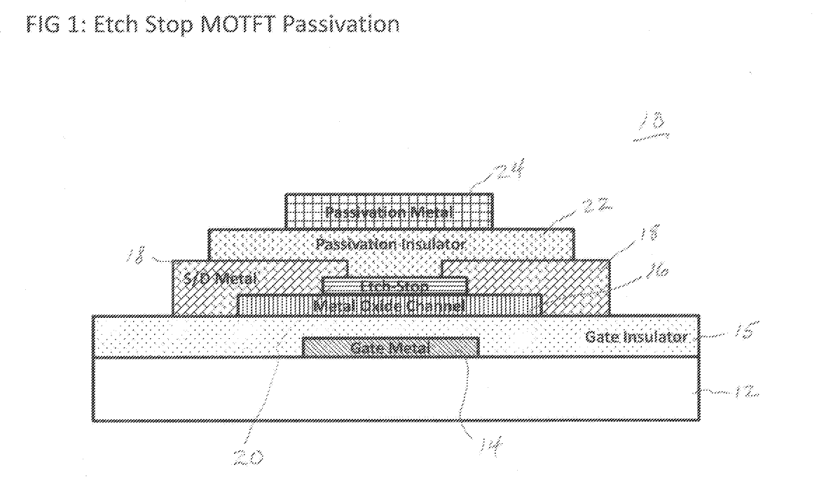

Turning to FIG. 1, an etch-stop type of MOTFT 10 is illustrated with passivation in accordance with the present invention. MOTFT 10 includes a substrate (support structure) 12, which may be rigid, flexible, transparent, opaque, silicon, glass, plastic, stainless steel with a dielectric coating or any material capable of providing support for MOTFT 10. A metal gate 14 is positioned on substrate 12 by any convenient means, preferably by non-critical patterning. Here it should be understood that while a single MOTFT is illustrated and described for convenience, MOTFT 10 could be part of a back-panel circuit for a flat panel display array, sensor array, etc. Thus, a large number of metal gates 14 may be simultaneously placed on substrate 12 and, since the placement is generally not critical, non-critical patterning can be used.

A thin gate insulator/dielectric layer 15 is deposited over gate 14, preferably in a blanket deposition. A metal oxide film 16 is formed on gate dielectric layer 15 in overlying relationship to metal gate 14 and the surrounding area. Metal oxide film 16 is the semiconductor active layer for MOTFT 10. Examples of metal oxides that can be used include zinc oxide (ZnO), indium oxide (InO), tin-oxide (SnO), gallium-oxide (GaO), indium zinc oxide (InZnO), tim-zink oxide (SnZnO), indium zinc gallium oxide (InZnGaO), indium tin zinc oxide (InSnZnO), indium aluminum zinc oxide (InAlZnO), indium silicon zinc oxide (InSiZnO), and similar materials or combinations thereof in blend, multiple layers or alloy forms. Also, the metal oxide semiconductor may be amorphous or polycrystalline, however, amorphous, or nanocrystalline with mean grain size substantially smaller than the TFT channel length (say, <100 nm) is preferred. An etch-stop/passivation area 20 is patterned on metal oxide layer 16 and source/drain terminals 18 are formed on opposite sides of passivation area 20 on the upper surface of active layer 16. The space between the source/drain terminals 18 defines the conduction channel for MOTFT 10. Additional information as to preferred methods of fabrication of MOTFT 10 are available in U.S. Pat. No. 7,977,151, entitled “Double Self-Aligned Metal Oxide TFT”, issued Jul. 12, 2011, U.S. Pat. No. 8,679,905, entitled “Metal Oxide TFT with improved source/drain contacts”, issued Mar. 25, 2014, U.S. Pat. No. 9,356,156, issued on May 31, 2016, entitled “Stable High Mobility MOTFT and Fabrication at Low Temperature”, issued May 31, 2016. They are incorporated herein by reference.

Any passivation of a MOTFT requires three characteristics. First, the passivation material has to have very little chemical interaction with the metal oxide and with oxygen at subsequent processing temperatures and during useful lifetime. Any strong chemical interaction will move the threshold voltage. Second, the passivation material has to have very little diffusion for processing and ambient gases, such as hydrogen, oxygen, and water, at high temperature. Third, the material has to be electrically insulating from the metal oxide. The third requirement or constraint limits the choice of material to an insulator.

The insulator films that can be deposited on top of metal oxide without destroying the MOTFT are typically porous to oxygen and water. Examples are organic polymers (e.g. polyimide film from Toray Films or DuPont Teijin Films, acrylic films from JSR Corporation, Fuji Films or MicroChem, Bisbenzocyclobutene resins (BCB), SU8 film from MicroChem, poly(4-vinylphenol) (PVP) and its crosslinked version with 4,4′-(hexafluoroisopropylidene)diphthalic anhydride (PVP:HDA)) and PECVD SiO₂, spin on insulators such as ZrO, sol gel and spin-on glasses, sputtered oxide (e.g. AlO, SiO₂). Once an insulator film of this type is deposited on the metal oxide, the structure can be annealed in the air at elevated temperature to restore the oxygen vacancy balance in the metal oxide active channel layer, if necessary. This restoration can be accomplished since oxygen diffuses through the insulator layers described under elevated temperature.

Turning again to FIG. 1, a passivation insulator film 22 is deposited over source/drain terminals 18 and passivation area 20 of MOTFT 10. Passivation insulator film 22 is one of the more porous insulators such as an organic polymer film, a PECVD SiO₂ or SiON film, or any of the insulating materials described above. MOTFT 10 is then annealed back into oxygen vacancy equilibrium.

With insulator film 22 in place and metal oxide active layer 16 in oxygen vacancy equilibrium, a dense metal film 24 is deposited on insulator film 22 so as to cover and protect the space between source/drain terminals 18, which defines the conduction channel for MOTFT 10. For film 24 an inert metal, such as a noble metal (Au, Ag, Pd, Pt, etc.), a refractory metal (Mo. W, etc.) or any of the transparent metal oxides known in the semiconductor industry, such as ITO, SnO, AlSnO or AlZnO and the like, can be deposited by sputtering at low temperature. The inertness of the metal is manifested in its work function, generally being a high work function (>4.5 eV). In at least some instances the noble or refractory metal can be replaced by a transparent metal oxide, such as ITO, SnO, AlSnO or AlZnO. In yet other instances, a stack metal film comprising multiple inert metals, refractory metals or transparent metal-oxides explained above can also be used. By putting a dense layer of inert metal or metal oxide on insulator film 22, a composite film (polymer/metal or insulator/metal stack) is provided that is a good passivation film for MOTFTs (i.e. fulfills the three requirements listed above).

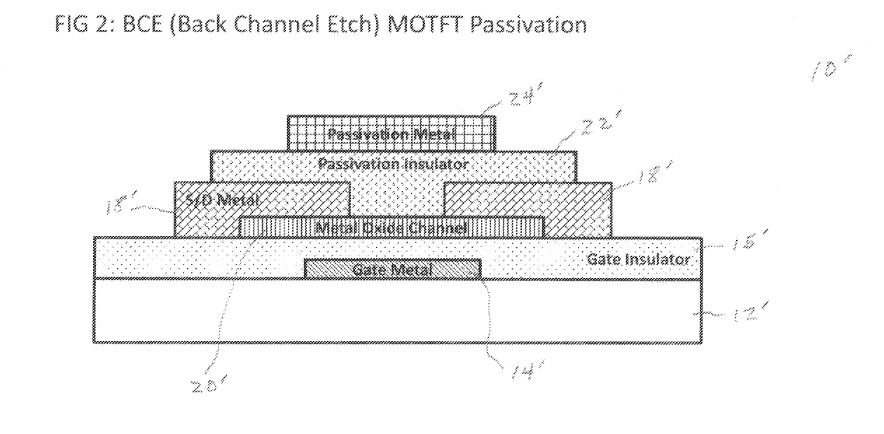

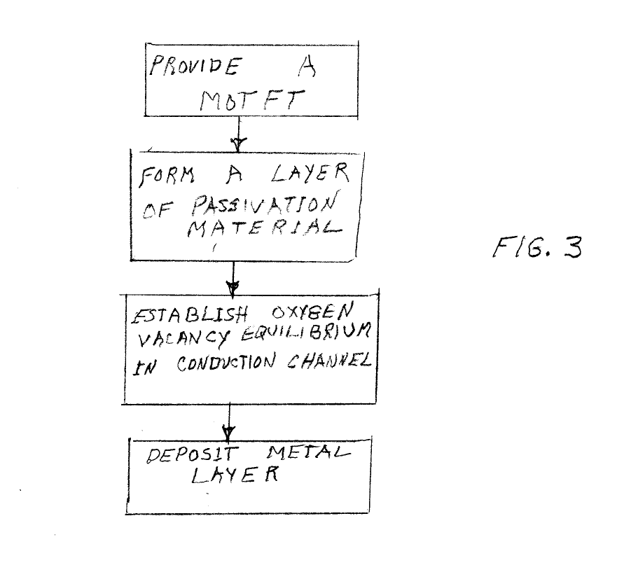

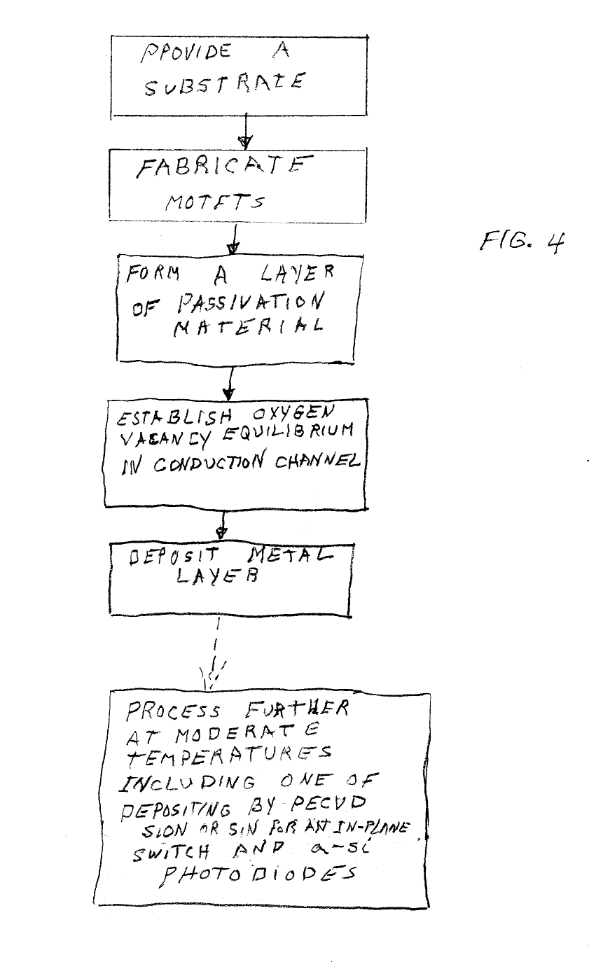

Turning to FIG. 2, a back channel etch type of MOTFT 10′ is illustrated with passivation in accordance with the present invention. MOTFT 10′ is similar to MOTFT 10 with similar components designated with similar numbers and a prime (′) is added to indicate a different structure. MOTFT 10′ does not include etch-stop/passivation area 20 and source/drain terminals 18′ are formed by etching directly a blanket layer of conductive metal. In MOTFT 10′ the conduction channel (defined by the space between the source/drain terminals 18′), is exposed to the ambient. A passivation insulator film 22′ is deposited over source/drain terminals 18′ and the conduction channel of MOTFT 10′. Passivation insulator film 22′ is one of the more porous insulators such as an organic polymer film, a PECVD SiO₂ film, or any of the insulating materials described above. MOTFT 10′ is then annealed back into oxygen vacancy equilibrium. With insulator film 22′ in place and metal oxide active layer 16′ in oxygen vacancy equilibrium, a dense metal film 24′ (similar to film 24 above) is deposited on insulator film 22′ so as to cover and protect the space between source/drain terminals 18′, which defines the conduction channel for MOTFT 10′. Thus, a composite film (polymer/metal or insulator/metal stack) is provided that is a good passivation film for MOTFT 10′.

Thus, the present invention provides a new and improved process for passivation of MOTFTs that improves environmental stability. Further, the present invention provides a new and improved process and material for passivation of MOTFTs that is compatible with flat panel technology. By depositing a more porous insulating film, annealing in oxidizing ambience to establish oxygen vacancy equilibrium, and depositing a dense inert/refractory metal and/or metal oxide layer a composite film (polymer/metal or insulator/metal stack) is provided that is a good passivation film for MOTFTs. Deposition of the dense metal layer is performed at low temperature which will not destroy the MOTFT. The dense metal is insulated from direct contact with the metal oxide (and, incidentally, the source/drain contacts) by the insulating film and insulated from the MOTFT. The composite film serves as a good barrier for external ambience, such as hydrogen, oxygen and water vapor, at moderate temperature (>200° C., <250° C.). On the other hand, oxygen from the metal oxide tends to diffuse through the insulating layer at elevated temperature. The dense metal layer serves as a barrier for the internal oxygen outflow. The oxidation of the inert metal at moderate temperature is slow enough that the threshold voltage of the MOTFT is not greatly changed.

The improved passivating structure (composite film) enables further processing at moderate temperature after MOTFT fabrication. Moderate temperature (200° C. to 250° C.) processes are needed in In-Plane-Switch LCD for PECVD SiON or SiN deposition. For X-ray imagers, there is a need to deposit a-Si photodiodes by PECVD at around 200° C. The improved passivating structure also allows the fabrication of a-Si photodiodes after the MOTFT back-plane is finished without destroying the MOTFTs in the photodiode fabrication process or the SiN passivation process for the photodiodes.

Various changes and modifications to the embodiment herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of passivating a metal oxide thin film transistor comprising the steps of:
providing a metal oxide thin film transistor having a surface defined by spaced apart source/drain terminals positioned on a layer of semiconductor metal oxide and material in a space between the source/drain terminals, the space between the source/drain terminals defining a conduction channel in the layer of semiconductor metal oxide;
forming a layer of passivation material on the surface defined by the spaced apart source/drain terminals and the material in the space between the source/drain terminals;
establishing oxygen vacancy equilibrium in the conduction channel of the layer of semiconductor metal oxide by annealing in an oxygen containing ambient the metal oxide thin film transistor and layer of passivation material; and
depositing a layer including inert metal, refractory metal or transparent metal oxide on the layer of passivation material overlying the space between the source/drain terminals.

2. A method as claimed in claim 1 wherein the step of providing the metal oxide thin film transistor includes providing one of an etch-stop type of thin film transistor or a back channel etch type of thin film transistor.

3. A method as claimed in claim 2 wherein the step of providing the metal oxide thin film transistor includes providing a transistor wherein the material in the space between the source/drain terminals is an etch-stop material or the layer of semiconductor metal oxide.

4. A method as claimed in claim 1 wherein the step of forming the layer of passivation material includes forming a layer of one of organic polymers, including polyimide film, acrylic films, Bisbenzocyclobutene resin film (BCB), SU8 film, poly(4-vinylphenol) (PVP) and its crosslinked version with 4,4′-(hexafluoroisopropylidene)diphthalic anhydride (PVP:HDA), or PECVD SiO₂, SiON, spin on insulators including ZrO, sol gel, spin-on glasses, or sputtered oxide including one of Al₂O₃ or SiO₂.

5. A method as claimed in claim 1 wherein the step of depositing the layer including inert metal, refractory metal or transparent metal oxide includes depositing a metal material having a work function greater than 4.5 eV.

6. A method as claimed in claim 1 wherein the step of depositing the layer including inert metal, refractory metal or transparent metal oxide includes depositing a layer of one of a noble metal, a refractory metal, a transparent conducting oxide including ITO, SnO, AlSnO or AlZnO, or a film stack comprising multiple sub-layers of a noble metal, a refractory metal, and/or a transparent conducting metal oxide.

7. A passivated metal oxide thin film transistor comprising:
a metal oxide thin film transistor having a surface defined by spaced apart source/drain terminals positioned on a layer of semiconductor metal oxide and material in a space between the source/drain terminals, the space between the source/drain terminals defining a conduction channel in the layer of semiconductor metal oxide;
a layer of passivation material on the surface defined by the spaced apart source/drain terminals and the material in the space between the source/drain terminals; and
a layer including a noble metal, a refractory metal, and/or a transparent conducting metal oxide on the layer of passivation material overlying the space between the source/drain terminals.

8. A passivated metal oxide thin film transistor as claimed in claim 7 wherein the metal oxide thin film transistor includes one of an etch-stop type of thin film transistor and a back channel etch type of thin film transistor.

9. A passivated metal oxide thin film transistor as claimed in claim 7 wherein the metal oxide thin film transistor includes a transistor wherein the material in the space between the source/drain terminals is an etch-stop material or the layer of semiconductor metal oxide.

10. A passivated metal oxide thin film transistor as claimed in claim 7 wherein the layer of passivation material includes a layer of one of organic polymers including polyimide film from Toray Films or DuPont Teijin Films, acrylic films from JSR Corporation, Fuji Films or MicroChem, Bisbenzocyclobutene resin film (BCB), SU8 film from MicroChem, poly(4-vinylphenol) (PVP) and its crosslinked version with 4,4′-(hexafluoroisopropylidene) diphthalic anhydride (PVP:HDA), or PECVD SiO₂, SiON, or spin on insulators including ZrO, sol gel and spin-on glasses, or sputtered oxide including one of Al₂O₃ or SiO₂.

11. A passivated metal oxide thin film transistor as claimed in claim 7 wherein the layer including a noble metal, a refractory metal, and/or a transparent conducting metal oxide includes a metal material having a work function greater than 4.5 eV.

12. A passivated metal oxide thin film transistor as claimed in claim 7 wherein the transparent conducting metal oxide includes one of ITO, SnO, AlSnO or AlZnO, and the layer including a noble metal, a refractory metal, and/or a transparent conducting metal oxide includes a film stack comprising multiple sub-layers of a noble metal, a refractory metal, and/or a transparent conducting metal oxide.

13. A method of fabricating a back-panel with a plurality of metal oxide thin film transistors for flat panel devices including one of a light emitting diode display, an image sensor array, a biosensor array, a pressure sensing array, an X-ray imager, or a touch sensing array, the method comprising the steps of:
providing a substrate; and
fabricating on the substrate a plurality of passivated metal oxide thin film transistors, the fabrication of each passivated transistor including the steps of:
providing a metal oxide thin film transistor having a surface defined by spaced apart source/drain terminals positioned on a layer of semiconductor metal oxide and material in a space between the source/drain terminals, the space between the source/drain terminals defining a conduction channel in the layer of semiconductor metal oxide;
forming a layer of passivation material on the surface defined by the spaced apart source/drain terminals and the material in the space between the source/drain terminals;
establishing oxygen vacancy equilibrium in the conduction channel of the layer of semiconductor metal oxide by annealing in an oxygen containing ambient the metal oxide thin film transistor and layer of passivation material; and
depositing a layer including a noble metal, a refractory metal, and/or a transparent conducting metal oxide on the layer of passivation material overlying the space between the source/drain terminals.

14. A method as claimed in claim 13 further including, subsequent to the step of depositing a layer including a noble metal, a refractory metal, and/or a transparent conducting metal oxide, a step of processing at moderate temperature in a range of 200° C. to 250° C. an In-Plane-Switch LCD on the plurality of passivated metal oxide thin film transistors, the step of processing including depositing by PECVD SiON or SiN.

15. A method as claimed in claim 13 further including, subsequent to the step of depositing a layer including a noble metal, a refractory metal, and/or a transparent conducting metal oxide, a step of processing at moderate temperature in a range of 200° C. to 250° C. an X-ray imager on the plurality of passivated metal oxide thin film transistors, the step of processing including depositing a-Si photodiodes by PECVD.
